(19) United States
(12) Patent Application Publication
(10) Pub. No.: US 2026/0242289 A1
(43) Pub. Date: Aug. 20, 2026

(54) METAL-CERAMIC SUBSTRATE AND PROCESS FOR PRODUCING A METAL-CERAMIC SUBSTRATE

(71) Applicant: Rogers Germany GmbH, Eschenbach (DE)

(72) Inventors: Stefan Britting, Schnaittach (DE); Karsten Schmidt, Eschenbach (DE)

(21) Appl. No.: 19/156,083

(22) PCT Filed: Feb. 13, 2024
(86) PCT No.: PCT/EP2024/053560

§ 371 Date: Aug. 13, 2025

(30) Foreign Application Priority Data
Feb. 16, 2023 (DE) 10 2023 103 850.8

(51) Int. Cl. C04B 35/04; C04B 37/02

(52) U.S. Cl. CPC C04B 35/04; C04B 37/021; C04B 2235/3206; C04B 2235/3208; C04B 2235/3217; C04B 2235/3225; C04B 2235/3244; C04B 2237/34; C04B 2237/40; C04B 2237/704; C04B 2237/706

(57) ABSTRACT

Metal-ceramic substrate that can be used as a printed circuit board, comprising
a ceramic element and
at least one component metallisation, which is bonded to the ceramic element, wherein the component metallisation is structured in order to form conductor paths,
   wherein the ceramic element comprises magnesium oxide and wherein a proportion of magnesium oxide is greater than 60 wt %, preferably greater than 80% and more preferably greater than 95 wt %.

### CROSS REFERENCE TO RELATED APPLICATIONS

This application is a National Stage application of PCT/EP2024/053560, filed Feb. 13, 2024, which claims the benefit of German Application No. 10 2023 103850.8, filed Feb. 16, 2023, both of which are incorporated by reference in their entirety herein.

### BACKGROUND

The present invention relates to a metal-ceramic substrate and a method for producing a metal-ceramic substrate.

Metal-ceramic substrates are well known in the prior art as printed circuit boards or circuit boards, for example from DE 10 2013 104 739 A1, DE 19 927 046 B4 and DE 10 2009 033 029 A1. Typically, connecting areas for electrical components and conductor paths are arranged on one component side of the metal-ceramic substrate or of the metal-ceramic substrate, wherein the electrical components and the conductor paths can be interconnected to form electrical circuits. Essential components of the metal-ceramic substrates are an insulating layer, which is preferably produced from a ceramic, and at least one metal layer bonded to the insulating layer. Due to their comparatively high insulation strengths, insulating layers produced from ceramics have proven to be particularly advantageous in power electronics. Conductor paths and/or connecting areas for the electrical components can then be realized by structuring the metal layer.

Based on the prior art, it is an object of the present invention to provide a metal-ceramic substrate which is further improved over the known metal-ceramic substrates, in particular with regard to the thermal shock resistance of the bond between the metal layer and the ceramic element and a dissipation of heat when heat is generated on the component side of the metal-ceramic substrate during operation.

### SUMMARY

The present invention solves this object with the disclosed metal-ceramic substrate and a method for producing the disclosed metal-ceramic substrate. Further embodiments are described in the dependent claims and the description.

According to a first aspect of the present invention, a metal-ceramic substrate is provided which can be used as a printed circuit board, comprising
a ceramic element and
at least one component metallisation, which is bonded to the ceramic element, wherein the at least one component metallisation is structured to form conductor paths,
   wherein the ceramic element comprises magnesium oxide, wherein a proportion of magnesium oxide is greater than 60 wt %, preferably greater than 80 wt % and more preferably greater than 95 wt %.

### BRIEF DESCRIPTION OF THE DRAWINGS

Further advantages and properties are apparent from the following description of preferred embodiments of the invention with reference to the accompanying figures. The following is shown:

FIG. 1 shows a metal-ceramic substrate according to a first exemplary embodiment;

FIG. 2 shows a metal-ceramic substrate according to a second exemplary embodiment; and

FIG. 3 shows a metal-ceramic substrate according to a third exemplary embodiment;

### DETAILED DESCRIPTION

Compared to the metal-ceramic substrates known from the prior art, the metal-ceramic substrate uses a ceramic element with a comparatively high magnesium oxide content. In particular, the ceramic element consists essentially exclusively of magnesium oxide. By consisting exclusively of magnesium oxide, the skilled person understands in particular a magnesium oxide content which has a value between 95 wt % and 100 wt %. Surprisingly, it has been shown that magnesium oxide can be used to provide a ceramic element that has a comparatively high thermal conductivity, which has a positive effect on the thermal shock resistance of the produced metal-ceramic substrate. This significantly improves the bonding process of the at least one metal layer to the ceramic element and the service life of the metal-ceramic substrate. In particular, it is provided that at least one metal layer is bonded to the ceramic element and, after the bonding process, conductor paths and/or connecting areas are formed as part of structuring so that the metal-ceramic substrate can be used as a printed circuit board. The bonded and structured at least one metal layer then forms the component metallisation. In particular, it has been shown that the coefficient of thermal expansion of magnesium oxide typically has a value between 11×10⁻⁶ 1/K and 13×10⁻⁶ 1/K, which is relatively close to that of copper, so that the difference between the coefficients of thermal expansion is as small as possible, particularly when bonding a copper metal layer to the ceramic element. This has a positive effect on thermal shock resistance and reduces the formation of thermomechanical stress during temperature changes. This significantly improves the service life of the metal-ceramic substrates, especially when they are used as printed circuit boards. Furthermore, it is preferred that the thermal conductivity has a value greater than 30 W/mK, more preferably between 40 and 59 W/mK and more preferably between 55 and 59 W/mK.

Furthermore, magnesium oxide proves to be a comparatively inexpensive alternative to aluminium oxide or HPS ceramics, which at the same time have a comparatively high thermal conductivity.

It is preferably provided that the component metallisation has a first thickness and the backside metallization, which is bonded to the ceramic element on the side opposite the component metallisation, has a second thickness. The ceramic element has a third thickness. Preferably, the third thickness has a value between 100 μm and 1000 μm and the second and/or first thickness has a value between 200 and 800 μm. It is more preferably provided that the second thickness and the first thickness correspond to each other in order to counteract any deflections during a bonding process of the at least one metal layer to the ceramic element. It is also conceivable that the third thickness is smaller than the first thickness and/or second thickness.

It is preferably provided that the ceramic element comprising magnesium oxide is doped with an accompanying material. In particular, the accompanying material is selected such that it does not impair the thermal conductivity, in particular such that it leads to deviations in the thermal conductivity, which are less than 50%, preferably less than 25% and more preferably less than 20% of the thermal conductivity of the magnesium oxide. It is preferably provided that a proportion of the accompanying material in the ceramic element has a value which is less than 10 wt %, in particular less than 5 wt % and more preferably less than 3 wt %. This makes it advantageously possible to influence and in particular improve further properties of the magnesium oxide by this doping. For example, it is possible to increase the density or strength by means of the accompanying material, thus further increasing the mechanical stability of the ceramic element. This in turn allows, for example, the ceramic element to be designed thinner.

Accompanying materials that contribute to spinel formation, such as Al₂O₃, and/or reinforcement, such as ZrO₂, are conceivable. The ability to bond to copper is preferably improved by an accompanying material such as copper or a mixture of copper and Al₂O₃. Due to their grain sizes and the associated strength, CaO and Y₂O₃ are also preferred accompanying materials. The use of ZrO₂ in particular proves to be particularly advantageous for the material structure, as this leads to a conver-sion enhancement.

It is preferably provided that magnesium oxide has a density which has a value between 3 and 4 g/cm³ , preferably a value between 3.1 and 3.8 g/cm³ and more preferably between 3.35 and 3.58 g/cm³ . The value of the density refers to the value present in the produced metal-ceramic substrate. This provides a comparatively high-density magnesium oxide, which has advantageously high thermal conductiv-ities.

It is preferably provided that the ceramic element comprises a coating, in particular a ceramic coating, preferably an aluminium oxide coating, which is arranged between the ceramic element and the component metallization. This proves particularly advantageous during the bonding process because the realized ceramic coating acts as an additional bonding agent and, in particular, helps to solidify the surface through spinel formation (magnesium aluminium oxide).

The materials for the at least one metal layer or the component metallisation in the metal-ceramic substrate are copper, aluminium, molybdenum, tungsten, nickel and/or their alloys such as CuZr, AlSi or AlMgSi, as well as laminates such as CuW, CuMo, CuAl and/or AICu or MMC (metal matrix composite), such as CuW, CuM or AlSiC, conceivable. Furthermore, it is more preferably provided that the at least one metal layer on the produced metal-ceramic substrate, in particular as component metallisation, is surface-modified. As a surface modification, for example, a seal with a precious metal, in particular silver; and/or gold, or (electroless) nickel or ENIG (“electroless nickel immersion gold”) or an edge encapsulation on the metallisation to suppress crack formation or propagation is conceivable.

According to a preferred embodiment of the present invention, it is provided that in the produced metal-ceramic substrate a bonding layer is formed between the component metallisation and the ceramic element, wherein a bonding agent layer of the bonding layer has a sheet resistance, which is greater than 0.5 ohms/sq, preferably greater than 1 ohm/sq and more preferably greater than 2 ohms/sq or even greater than 15 ohms/sq.

The sheet resistance is directly related to the proportion of active metal in the bonding agent layer, which is decisive for the bonding of the at least one metal layer to the ceramic element. The sheet resistance increases with decreasing active metal content in the bonding layer. A correspondingly high sheet resistance therefore corresponds to a low active metal content in the bonding agent layer.

The sheet resistance does not depend on a single parameter, but can be influenced by the interaction of several parameters. For example, a purity of the active metal, a thickness of the bonding layer and/or a surface roughness of the ceramic element also contribute to determining the sheet resistance. In particular, high sheet resistances can only be achieved through the interaction of at least two parameters.

It has been shown that an increasing proportion of active metal promotes the formation of brittle, intermetallic phases, which in turn is detrimental to a pull-off strength of the metal layer on the insulating layer. In other words, with the disclosed sheet resistances such bonding layers are described, whose pull-off strength is improved, i.e. increased, due to the reduced formation of brittle intermetallic phases. By specifically adjusting the disclosed sheet resistances, particularly strong bonds of the at least one metal layer to the ceramic element can be achieved. Such increased bonding strength has a beneficial effect on the service life of the metal-ceramic substrate. In order to determine the sheet resistance, it is provided that the metal layer and, if necessary, a solder base layer are removed from the produced metal-ceramic substrate, for example by etching. A sheet resistance is then measured on the outer side or bottom side of the metal-ceramic substrate freed from the at least one metal layer and the solder base layer by means of a four-point measurement. In particular, the sheet resistance of a material sample is understood to be its resistance relative to a square surface area. It is customary to designate the surface resistance in ohms/sq (square). The physical unit of sheet resistance is ohms. It is preferably provided that a thickness of the bonding layer measured in the stacking direction, averaged via a plurality of measuring points within a predetermined area or in a plurality of areas running parallel to the main extension plane, has a value which is less than 0.20 mm, preferably less than 10 μm and more preferably less than 20 μm. Where reference is made to a plurality of areas, this means in particular that the at least one metal layer is divided into areas of as equal a size as possible and that at least one value, preferably several measured values, for the thickness is recorded in each of these areas dividing the at least one metal layer. The thicknesses determined in this way at different locations are arithmetically averaged.

Compared to the metal-ceramic substrates known from the prior art, a comparatively thin bonding layer is thus formed between the at least one metal layer and the ceramic element. It is provided that, in order to determine the relevant thickness of the bonding layer, the measured thicknesses are averaged via a plurality of measuring points, which are located within a predetermined or defined area or the plurality of areas. This advantageously takes into account the fact that the ceramic element is usually subject to undulation, i.e., the ceramic element has a degree of waviness. In particular, the skilled person understands a waviness to be a modulation of the general flat course of the ceramic element, seen via several millimeters or centimeters along a direction running parallel to the main extension plane. This distinguishes such an undulation from a surface roughness of the ceramic element, which is usually additionally present on the ceramic element. By including such an undulation of the ceramic element, which is generally unavoidable, in the determination of the thickness, it is taken into account that the bonding layer may vary due to the undulation, in particular may be greater in valley areas of the ceramic element than in mountain areas of the ceramic element.

Preferably, the proportion of active metal in the bonding agent layer comprising an active metal is greater than 25 wt %, preferably greater than 20 wt % and more preferably greater than 15 wt %.

Preferably, the bonding layer is formed flat, in particular without discontinuity, i.e. continuously, between the at least one metal layer and the ceramic element. It is preferably provided that a ratio of a region, in which no bonding layer is formed between the at least one metal layer and the ceramic element to the regions, in which a bonding layer is formed between the at least one bonding layer and the ceramic element is less than 0.05 mm, preferably less than 0.02 mm and more preferably less than 0.007 mm. The skilled person understands in particular that, in order to form this ratio, the areas, which are free of metal of the at least one metal layer due to the structuring are not taken into account.

In particular, it is provided that the component metallisation is bonded via a direct bonding method. In a direct bonding method or a hot isostatic pressing, unlike in an active soldering process, the structure is not weakened or only slightly weakened, resulting in a mechanically stable metal-ceramic substrate.

It is also conceivable that the component metallisation has a thickness greater than 0.4 mm, preferably greater than 1.0 mm and more preferably greater than 1.5 mm. This has the advantage of ensuring sufficient mechanical stability, even if the bonding process weakens the structure.

It is preferred that the ceramic element has a thickness greater than 200 μm, preferably greater than 300 μm and more preferably greater than 400 μm. This allows, in particular in combination with a comparatively thick metal layer, a mechanically particularly stable metal-ceramic substrate to be provided, which can be used in many areas of application.

Another subject of the present invention is a method for producing a metal-ceramic substrate according to the present invention.

In particular, a method for producing a metal-ceramic substrate usable as a printed circuit board, in particular a metal-ceramic substrate according to one of the pre-ceding claims, is provided, comprising:
providing a ceramic element comprising magnesium oxide and a metal layer,
bonding the metal layer to the ceramic element, and
structuring the metal layer in order to form a component metallisation. All advantages and properties described for the metal-ceramic substrate apply analogously to the method for producing the metal-ceramic substrate according to the invention and vice versa. In particular, the method comprises providing a ceramic element with a specific surface roughness and/or producing a surface profile on the outer side of the ceramic element.

Furthermore, it is more preferably provided that the at least one metal layer and/or the at least one further metal layer is bonded to the ceramic element by means of an active soldering process and/or hot isostatic pressing and/or a DCB process.

For example, a method for producing a metal-ceramic substrate is provided, comprising:
providing a solder layer, in particular in the form of at least one solder foil or brazing foil,
coating the ceramic element and/or the at least one metal layer and/or the at least one solder layer with at least one active metal layer,
arranging the at least one solder layer between the ceramic element and the at least one metal layer along a stacking direction to form a solder system comprising the at least one solder layer and the at least one active metal layer, wherein a solder material of the at least one solder layer is preferably free of a material, which lowers the melting point, or of a phosphorus-free material, and
bonding the at least one metal layer to the at least one ceramic layer via the solder system by means of an active soldering process.

In particular, a multi-layer soldering system comprising at least one solder layer, preferably free of elements lowering the melting point, more preferably comprising a phosphorus-free solder layer, and at least one active metal layer is provided. The separation of the at least one active metal layer and the at least one solder layer proves to be particularly advantageous because it allows comparatively thin solder layers to be produced, especially if the solder layer is a foil. For active metal-containing solder materials, comparatively large solder layer thicknesses would otherwise be necessary due to the brittle intermetallic phases or the high modulus of elasticity and high yield strength of the common active metals and their intermetallic phases, which prevent the deformation of the solder paste or solder layer, thus limiting the minimum layer thickness due to the manufacturing properties of the solder material containing active metal. Accordingly, for solder layers containing active metal, it is not the minimum thickness required for the joining process that determines the minimum solder layer thickness, but rather the technically feasible minimum layer thickness of the solder layer that determines the minimum solder layer thickness. This makes this thicker solder layer containing active metal more expensive than thin layers. The term “phosphorus-free” is understood by the skilled person to mean in particular that the phosphorus content in the solder layer is less than 1000 ppm, preferably less than 500 ppm and more preferably less than 200 ppm.

Preferably, the solder layer, in particular the phosphorus-free solder layer, comprises several materials in addition to the pure metal. For example, indium is a component of the solder material used in the solder layer.

It is also conceivable that the solder material for forming the solder layer is deposited on the active metal layer and/or the at least one metal layer by physical and/or chemical vapor deposition and/or electroplating. This makes it possible, in an advantageous manner, to produce comparatively thin solder layers in the solder system, in particular in a homogeneous distribution.

For example, in the production of the metal-ceramic substrate, in particular the metal-ceramic substrate, further steps are provided, comprising:
providing a ceramic element and a metal layer,
providing a gas-tight container, which encloses the ceramic element, wherein the container is preferably formed from the metal layer or comprises the metal layer,
forming the metal-ceramic substrate by bonding the metal layer to the ceramic element by means of hot isostatic pressing,
   wherein, in order to form the metal-ceramic substrate, an active metal layer or a contact layer comprising an active metal is arranged at least in sections between the metal layer and the ceramic element in order to support the bonding of the metal layer to the ceramic element. The container is preferably formed as a metal container from a metal layer and/or a further metal layer. Alternatively, it is also conceivable that a glass container is used.

In hot isostatic pressing, it is provided in particular that the bonding takes place by heating under pressure, in which the first and/or second metal layer of the metal container, in particular the subsequent metal layer of the metal-ceramic substrate and any eutectic layer occurring there, does not pass into the melting phase. Similarly, hot isostatic pressing requires lower temperatures than a direct metal bonding method, in particular a DCB method.

Compared to bonding a metal layer to a ceramic layer using a solder material, which usually involves temperatures below the smelting temperature of the at least one metal layer, the present method has the advantage that a solder base material is not required and only an active metal is needed. The use or the utilization of pressure in hot isostatic pressing also proves to be advantageous because it can reduce air pockets or cavities between the first metal layer and/or the second metal layer on the one hand and the ceramic element on the other hand, thus reducing or even preventing the incidence of blowholes in the formed or produced metal-ceramic substrate. This has a beneficial effect on the quality of the bond between the metal layer or the first and/or second metal layer of the metal container and the ceramic element. In addition, it is advantageously possible to simplify the “second etching” and to avoid solder residues and silver migration.

It is also conceivable that during hot isostatic pressing, an additional solder material is introduced between the ceramic element and the at least one metal layer, wherein a smelting temperature of the additional solder material may be lower than the temperature at which the hot isostatic pressing is performed, i.e. lower than the smelting temperature of the at least one metal layer.

It is preferably provided that, during hot isostatic pressing, the metal container is subjected in a heating and pressure device to a gaseous pressure of between 100 and 2000 bar, preferably between 150 and 1200 bar and more preferably between 300 and 1000 bar and a processing temperature of 300° C. to a smelting temperature of the at least one metal layer, in particular to a temperature below the smelting temperature. It has been shown to be advantageous that it is thus possible to bond a metal layer, i.e., a first and/or second metal layer of the metal container, to the ceramic element without the temperatures required for a direct metal bonding method, for example a DCB or DAB method, and/or without a solder base material used in active soldering. In addition, the use or the utilization of an appropriate gaseous pressure makes it possible to produce a metal-ceramic substrate with as few cavities as possible, i.e., without gas inclusions between the metal layer and the ceramic element. In particular, process parameters mentioned in DE 2013 113 734 A1 are used, to which explicit reference is made herein.

It is preferably provided that the metal layer is bonded via an active metal layer. In particular, this is a separate active metal layer whose proportion of active metal is preferably more than 15 wt %, very preferably more than 35 wt %, and more preferably more than 80 wt %. This is therefore not an active metal-containing solder layer, but rather a bonding layer or bonding agent layer that merely uses active metal to achieve the bond between the metal layer and the ceramic element. Alternatively, it is preferable that the active metal layer is applied as a separate layer in addition to a solder base material, wherein the active metal layer and the solder base material form a solder layer system. In particular, it proves advantageous if the active metal layer is applied and/or used as an active metal foil.

It is more preferably provided that this is done under pressure, in particular in the context of hot isostatic pressing, thus advantageously also increasing the density of the magnesium oxide content in the ceramic element. For example, it is possible to increase the theoretical density of the magnesium oxide by 20%. The values for the density of the magnesium oxide are compared before and after hot isostatic pressing. In other words, the binding process also advantageously produces a high-density magnesium oxide.

It is preferably provided that the at least one metal layer is bonded by means of hot isostatic pressing, wherein in particular the density in the ceramic element is increased by the bonding.

Alternatively, it is conceivable that the at least one metal layer is bonded via a direct bonding method. In this case, it is conceivable, for example, that an additional ceramic coating surrounds the magnesium-enclosing ceramic element as a bonding agent, preferably to more than 75 wt %, more preferably to more than 85 wt % and most preferably to more than 95 wt %, and even completely surrounds it.

A ceramic coating made of aluminium oxide is particularly advantageous in this regard.

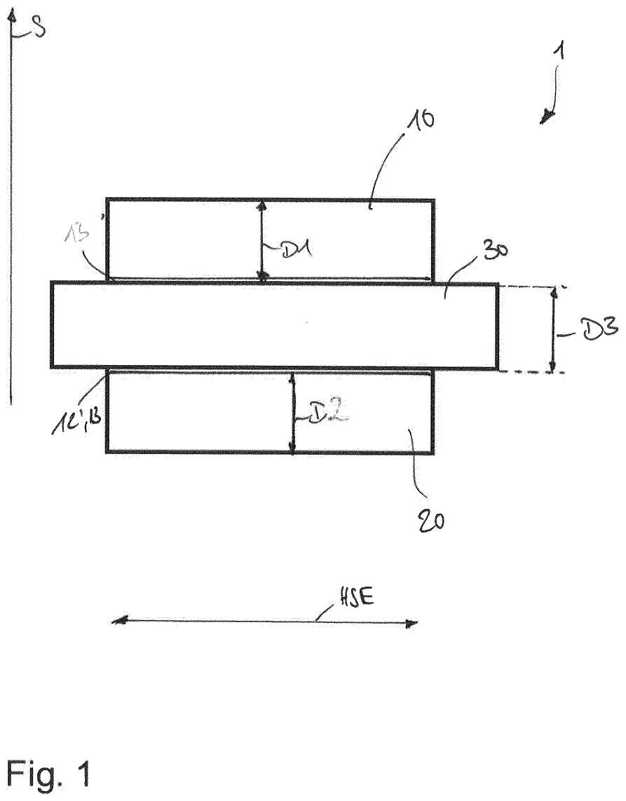

FIG. 1 shows a metal-ceramic substrate 1 according to a first exemplary embodiment of the present invention. Such metal-ceramic substrates 1 preferably serve as carriers or printed circuit boards for electronic or electrical components, to which at least one metal layer of the metal-ceramic substrate 1 can be bonded on the component side in order to form a component metallisation 10. It is preferably provided that the component metallisation 10 is structured in order to form corresponding conductor paths and/or connecting areas (not shown), i.e. in the produced metal-ceramic substrate 1, the component metallisation 10 comprises several metal sections, which are electrically insulated from one another. The component metallisation 10 extending essentially along a main extension plane HSE and a ceramic element 30 extending along the main extension plane HSE are arranged on top of one another along a stacking direction S running perpendicular to the main extension plane HSE and are preferably joined or connected to one another via a bonding layer 12. Preferably, the metal-ceramic substrate 1 comprises, in addition to the component metallization 10, at least one backside metallization 20 which, viewed in the stacking direction S, is arranged on the side of the ceramic element 30 opposite the component metallization 10 and is bonded to the ceramic element 30 via a further bonding layer 12′.

The at least one further metal layer 20 serves as backside metallization 20, which counteracts bending of the metal-ceramic substrate 1, in particular of the metal-ceramic element 1, and/or as a heat sink, which is designed to dissipate a heat input generated by electrical or electronic components on the metal-ceramic substrate 1.

In particular, the metal-ceramic substrate 1 has a bonding layer 12 arranged between the at least one metal layer 10 and the ceramic element 30. It has been shown to be advantageous if the thickness of the bonding layer 12, measured in the stacking direction S, is comparatively thin. In addition, a comparatively thin thickness of the bonding layer 12 between the at least one metal layer 10 and the ceramic element 30 proves to be advantageous if an etching process is provided for structuring the at least one metal layer 10. For example, narrower isolation trenches, i.e., distances between individual metal sections of the at least one metal layer 10, can be achieved.

Furthermore, the formation of a thinner bonding layer 12 proves to be advantageous in that it also further reduces the number of possible defects in the bonding layers 12 caused by material defects in any solder material used.

In the example shown in FIG. 1, the bonding layer 12 is in particular a bonding agent layer 13 comprising an active metal. In this case, after bonding, the bonding agent layer 13 is preferably formed from a material composition comprising a com-pound of components of the ceramic element on the one hand and an active metal on the other hand. Since these are very brittle bonds, it is advantageous for the adhesive strength of the at least one metal layer 10 on the ceramic element 30 if this bonding agent layer 13 is as thin as possible. For example, the bonding agent layer 13 can form the bonding layer 12 if, for example, an active metal layer, in particular an active metal foil, is arranged for the bonding process between the ceramic element 30 and the metal layer 10 and the bonding process takes place via hot isostatic pressing. However, the bonding agent layer 13 can also be formed, for example, by an active metal layer, in particular an active metal foil, which is arranged between the ceramic element 30 and a solder base layer in order to produce the bond between the metal layer 10 and the ceramic element 30 via the system consisting of the active metal layer and the solder base layer. In this case, the bonding agent layer 13 forms part of the bonding layer 12.

The active metal layer preferably has an active metal content greater than 15 wt %, preferably greater than 35 wt %, and more preferably greater than 80 wt %. This is therefore not an active metal-containing solder layer, which is used for bonding the at least one metal layer. It is more preferably provided that only one active metal layer is arranged between the ceramic element 30 and the at least one metal layer when the bonding process takes place.

In other words, for example, a solder base layer, which is additionally arranged between the ceramic element and the at least one metal layer, is dispensed with when the soldering process is performed in order to form the component metallisation 10. In particular, it is provided that after the bonding of the at least one metal layer in order to form the component metallisation 10, this at least one metal layer is structured, i.e. isolation trenches are introduced, which separate individual metal sections of the component metallisation 10 from one another in an insulating manner.

It has proven particularly advantageous to use magnesium oxide as the ceramic element 30. It is preferable that the proportion of magnesium oxide is more than 60 wt %, preferably more than 80 wt %, and more preferably more than 95 wt %. As a result, it is advantageous to use a comparatively inexpensive ceramic element, which has a comparatively high thermal conductivity. In addition, the coefficient of thermal expansion is comparable to that of copper. This has a positive effect on thermal shock resistance, since thermal stresses are less pronounced than with conventional ceramic materials.

Alternatively, it is conceivable that the bonding of the at least one metal layer to the ceramic element is performed via an active solder, i.e. by means of a solder layer containing an active metal. In this case, for example, the active metal content in the solder layer has a value of less than 15 wt %.

It is more preferably provided that the bonding of the at least one metal layer to the ceramic element 30 consisting of magnesium oxide or comprising magnesium oxide is carried out under pressure, if an active metal layer, preferably only one active metal layer, is arranged between the ceramic element 30 and the at least one metal layer, i.e. the intermediate region between the ceramic element and the at least one metal layer is free of a solder material or a solder base material. By ap-plying pressure when bonding the metal layer to the ceramic element 30, it is also advantageous to increase the density of the magnesium oxide, for example to a value greater than 75 TD, preferably greater than 85 TD and more preferably greater than 95 TD. The term TD refers for the skilled person in particular to the theoretical density, i.e. the smallest or tightest theoretically possible packing of the individual molecules in the solid of the ceramic element.

Furthermore, it is preferably provided that the component metallisation has a first thickness D1, the backside metallization has a second thickness D2 and the ceramic element has a third thickness. The first thickness D1, the second thickness D2 and the third thickness D3 are measured parallel to the stacking direction S. It is preferably provided that the first thickness D1 essentially corresponds to the second thickness D2 in order to thereby produce a desired symmetry, which counteracts bending during the production of the metal substrate. This is not absolutely necessary, for example, if the bonding takes place as part of a pressing process, since the pressing process itself counteracts bending. However, in conventional soldering processes, it proves to be particularly advantageous if the first thickness D1 and the second thickness D2 are essentially equal to each other. Preferably, the third thickness D3 has a value between 50 μm and 2 mm, more preferably between 100 μm and 1000 μm, and more preferably between 200 μm and 800 μm.

The first thickness D1 and/or second thickness D2 preferably have a value between 100 μm and 1000 μm, more preferably between 200 μm and 800 μm and most preferably between 300 μm and 700 μm. Furthermore, it is most preferably provided that the third thickness D3 is greater than the first thickness D1 and/or second thickness D2. It is also conceivable that the third thickness D3 is smaller than the first thickness D1 and/or second thickness D2.

The magnesium oxide preferably has a density of between 3 g/cm³ and 4 g/cm³ , preferably between 3.15 and 3.7 g/cm³ and more preferably between 3.3 and 3.56 g/cm³. Most preferably, the magnesium oxide in the ceramic element 30 has a proportion of 95 to 100%. This makes it advantageous to exploit the high thermal conductivity of the single crystal.

It is more preferably provided that the density of the magnesium oxide is increased by at least 20% by pressing.

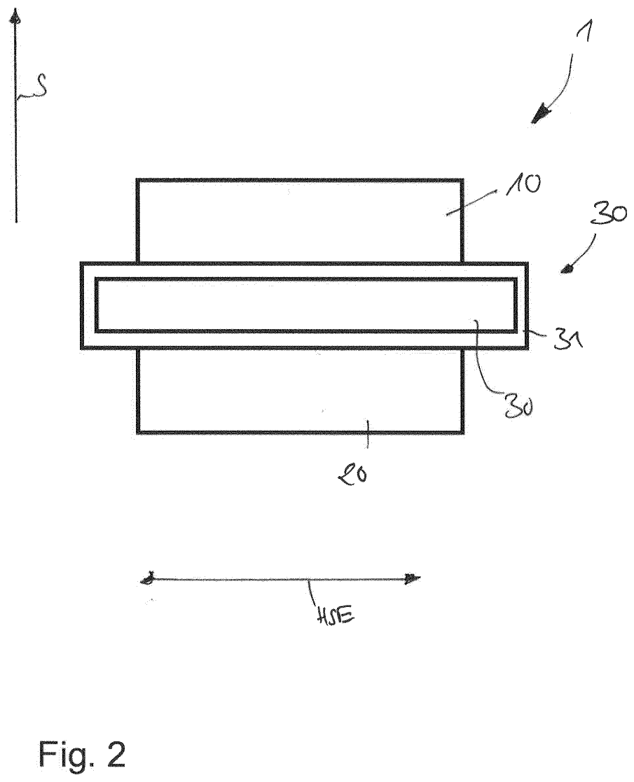

FIG. 2 shows a second embodiment of a metal-ceramic substrate 1 according to the present invention. In the embodiment shown here, the ceramic element 30 is surrounded, in particular completely surrounded, by a ceramic coating (for example made of aluminum oxide Al₂O₃). This coating 30 serves the purpose of improving or simplifying the bonding of the at least one metal layer to the insulating body. In particular, advantage is taken of the fact that the surface can be solidified by spinel formation, thus also enabling DCB bonding, i.e., direct connection.

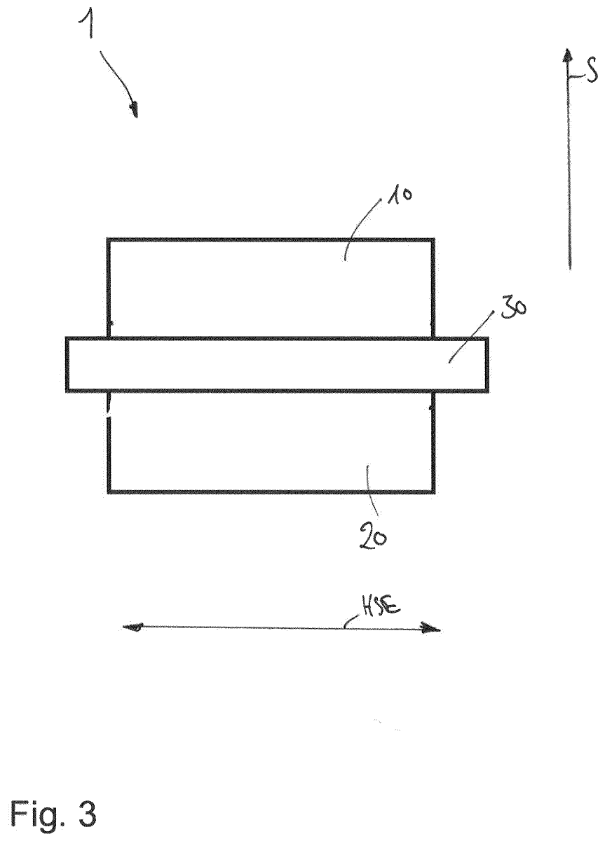

FIG. 3 shows a third embodiment of a metal-ceramic substrate 1 according to the present invention. In the embodiment shown here, it is provided that the at least one metal layer and/or the at least one further metal layer is bonded to the ceramic element 30 via a direct bonding method, in particular bonded directly to the ceramic element 30 comprising essentially magnesium oxide. In particular, the same material specifications apply to the magnesium oxide for all embodiments shown here. It is most preferably provided that a doped magnesium oxide is used or provided as the ceramic element 30.

For example, an additive or accompanying material is used as a dopant, the proportion of which in the ceramic element is less than 10 wt %, preferably less than 8 wt % and more preferably less than 5 wt %. In particular, the accompanying material, which is to be used for doping is selected such that it has as little influence as possible on the thermal conductivity. That is, the accompanying material used for doping leads to a change in the thermal conductivity of the ceramic element, wherein the change is less than 5%, preferably less than 2.5% and more preferably less than 1% of the measured thermal conductivity in a pure magnesium oxide ceramic element with comparable density.

### LIST OF REFERENCE NUMBERS

1 Metal-ceramic substrate
10 Component metallisation
12 Bonding layer
12 Additional bonding layer
13 Bonding agent layer
20 Backside metallization
30 Ceramic element
31 Coating
S Stacking direction
D1 First thickness
D2 Second thickness
D3 Third thickness

1-15. (canceled)

16. A metal-ceramic substrate (1), which can be used as a circuit board, comprising a ceramic element (30) and
at least one component metallisation (10), which is bonded to the ceramic element (30), wherein the at least one component metallisation (10) is structured to form conductor tracks,
wherein the ceramic element (30) comprises magnesium oxide and wherein a proportion of magnesium oxide in the ceramic element is greater than 60 wt %, wherein the magnesium oxide-comprising ceramic element (30) is doped with an accompanying material, characterized in that the accompanying material is selected such that it leads to a deviation in the thermal conductivity, which is less than 20% of the thermal conductivity of the magnesium oxide.

17. The metal-ceramic substrate according to claim 16, wherein the accompanying material is ZrO₂, Al₂O₃, CaO, Cu or Y₂O₃.

18. The metal-ceramic substrate (1) according to claim 16, wherein the magnesium oxide has a density, which has a value between 3 and 4 g/cm³ .

19. The metal-ceramic substrate (1) according to claim 16, wherein the ceramic element (30) comprises a coating (31), which is arranged between the ceramic element (30) and the component metallisation (10).

20. The metal-ceramic substrate (1) according to claim 16, wherein in the produced metal-ceramic substrate (1) a bonding layer (12) is formed between the component metallisation (10) and the ceramic element (30), wherein a bonding agent layer (13) of the bonding layer (12) has a sheet resistance, which is greater than 0.5 ohm/sq.

21. The metal-ceramic substrate (1) according to claim 16, wherein the component metallisation (10) is bonded via a direct bonding method.

22. The metal-ceramic substrate (1) according to claim 16, wherein the component metallisation (10) has a thickness, which is greater than 0.4 mm.

23. The metal-ceramic substrate (1) according to claim 16, wherein the ceramic element (30) has a thickness, which is greater than 200 μm.

24. A method for manufacturing a metal-ceramic substrate (1) usable as a circuit board according to claim 16, comprising:
providing a ceramic element (30) comprising magnesium oxide and a metal layer, bonding the metal layer to the ceramic element (30), and structuring the metal layer to form a component metallisation (10).

25. The method according to claim 24, wherein the metal layer is bonded via an active metal layer.

26. The method according to claim 24, wherein the at least one metal layer is bonded by means of hot isostatic pressing.

27. The method according to claim 24, wherein a density in the ceramic element (30) is increased by the bonding.

28. The method according to claim 24, wherein the metal layer is bonded via a direct bonding method.
